(19) United States
(12) Patent Application Publication
(10) Pub. No.: US 2024/0339302 A1
(43) Pub. Date: Oct. 10, 2024

(54) ELECTRICAL BREAK FOR SUBSTRATE PROCESSING SYSTEMS

(71) Applicant: Applied Materials, Inc., Santa Clara, CA (US)

(72) Inventors: Yogananda Sarode Vishwanath, Bangalore (IN); Andrew Nguyen, San Jose, CA (US); Tom K. Cho, Los Altos Hills, CA (US)

(21) Appl. No.: 18/206,456

(22) Filed: Jun. 6, 2023

(30) Foreign Application Priority Data
Apr. 10, 2023 (IN) 202341026632

(51) Int. Cl. H01J 37/32; B33Y 80/00

(52) U.S. Cl. CPC H01J 37/32449; B33Y 80/00; H01J 2237/334

(57) ABSTRACT

Systems, methods, and apparatus including designs embodied in machine-readable media for a gas break used in semiconductor processing systems. The apparatus includes a gas break structure comprising an insulating material and having one or more gas flow paths formed within a body of the gas break structure, the gas break structure configured to provide a specified impedance when coupled between a grounded gas distribution manifold and an electrically charged gas delivery nozzle, the gas break structure further comprising an internal structure having a specified geometry comprising a repeating structure and one or more empty gaps between elements of the repeating structure. The gas break can be formed using additive manufacturing.

### CROSS-REFERENCE TO RELATED APPLICATIONS

This application claims the benefit of priority under 35 U.S.C. § 119 to Indian Patent Application 202341026632, filed on Apr. 10, 2023, the contents of which are hereby incorporated by reference.

### BACKGROUND

This specification relates to semiconductor systems, processes, and equipment.

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

This specification describes technologies for a component used in a substrate processing system. In particular, this specification describes a radio frequency (“RF”) gas break component that provides an insulating barrier between a powered radio frequency plasma source and a gas supply line. The RF gas break component includes one or more gas flow paths configured to pass process gases from a gas line and to a gas delivery nozzle of a plasma-based processing chamber. The RF gas break is configured to provide a mixing of different component process gases and to provide an electromagnetic barrier that isolates a grounded input gas line from an electrically charged gas delivery nozzle. The one or more gas flow paths in the RF gas break further provide a particular gas conductance of process gases to a plasma processing chamber. In some implementations, the RF gas break component is designed and fabricated using additive manufacturing techniques. Using additive manufacturing allows for fabrication of the RF gas break with complex gas flow geometries and infill patterns.

The substrate processing system can be a plasma-based etching system in which etch processes are performed on layers of a substrate. During processing, an etching gas mixture flows through a gas delivery nozzle to form a plasma in a processing region of the chamber. Charged particles of the plasma are drawn towards an exposed surface of a substrate retained in the processing region of the chamber to perform an etching process on the exposed surface. Compositions of etching gas mixtures can be selected to etch different layer compositions, for example, a first etching gas mixture to etch silicon oxide (SiO) and a second etching gas mixture to etch silicon nitride (SiN). A semiconductor processing chamber can include one or more (e.g., two or more) processing regions, each with a respective substrate holder to retain a respective substrate and individually controllable etching gas mixtures to form a respective plasma in the processing regions.

The plasma is formed using a particular plasma source. One type of plasma source is a capacitively coupled plasma source. The plasma source supplies radio frequency energy to an electrode at the top of the plasma chamber that acts as a first parallel plate of a capacitor. The electrode can include the gas delivery nozzle. The etch gases are also supplied to the gas delivery nozzle using one or more gas lines. Because the gas delivery nozzle is electromagnetically charged, a gas break can be positioned between the gas line and the gas delivery nozzle to provide a specified level of impedance between the gas delivery nozzle and the gas line.

In general, one innovative aspect of the subject matter described in this specification can be embodied in a system for semiconductor processing. The system includes a chamber enclosing a first processing region and a first substrate support within the chamber and configured to retain a first substrate in the first processing region of the chamber. The system also includes a plasma source configured to direct RF energy into the chamber; a gas distribution manifold wherein the gas distribution manifold is operatively coupled to the chamber to introduce an etching gas including one or more gases from the gas distribution manifold to a gas delivery nozzle of the chamber. The system includes a gas break structure having an insulating material and having one or more gas flow paths formed within a body of the gas break structure, the gas break structure configured to provide a specified impedance when coupled between a grounded gas distribution manifold and an electrically charged gas delivery nozzle, the gas break structure further including an internal structure having a specified geometry including a repeating structure and one or more empty gaps between elements of the repeating structure.

In general, one other innovative aspect of the subject matter described in this specification can be embodied in a gas break structure embodied in a machine-readable medium for designing, manufacturing, or testing a design. The gas break structure includes a gas break body including an insulating material configured to provide a specified impedance. The gas break body has one or more gas flow paths formed within the body and having a particular path geometry. The gas break structure further includes an internal infill structure having a specified geometry having a repeating structure and one or more empty gaps between elements of the repeating structure.

In general, one other innovative aspect of the subject matter described in this specification can be embodied in a method of manufacturing a gas break structure. The method includes forming, by an additive manufacturing system, multiple layers. The multiple layers include a body having a solid outer surface and two or more gas flow paths defined within the body, wherein the two or more gas flow paths extend along a longitudinal length of the body, each gas flow path having a specified path geometry. The multiple layers further include an internal infill structure occupying a portion of the body, the internal infill structure having a specified geometry including structural elements and one or more hallow spaces between the structure elements.

Other embodiments of this aspect include corresponding systems, computer systems, apparatus, and computer programs recorded on one or more computer storage devices, each configured to perform the actions of the methods.

The subject matter described in this specification can be implemented in these and other embodiments so as to realize one or more of the following advantages. Using additive manufacturing (AM) techniques to manufacture an RF gas break can overcome challenges in the methods to manufacture the RF gas break, improve yield and increase complexity, as well as open up material possibilities. Design flexibility for gas path and internal structure geometries can be improved using AM. For example, AM can open up a design space for features of the RF gas break. For example, AM can be used to open a design space for gas flow paths such as placement/alignment, dimensions, and shape of the gas flow paths. In another example, AM can be used to introduce features otherwise unavailable or cost-prohibited by traditional, non-AM techniques, e.g., complex internal structures and gas flow path geometries. The gas flow path geometries can allow for longer gas flow paths without changing the external dimensions of the RF gas break. A longer gas flow path can provide greater control of gas conductance to the nozzle, which can further provide better control over etch rates in the plasma processing chamber.

AM techniques can result in improved control over fidelity (e.g., defect reduction) of manufactured parts resulting in better performance of the manufactured parts, e.g., improved impedance matching and repeatability between plasma processing chambers. For example, some conventional RF gas breaks are formed from two separate components—an inner component and an outer component—that are separately manufactured and press-fit together. Because these components are separately manufactured, e.g., by machining or molding a thermoplastic material, each resulting RF gas break component may vary in its impedance and gas flow characteristics. This increases the difficulty in getting impedance matching between multiple RF gas breaks on a single plasma processing chamber or between processing regions in a tandem chamber. Additionally, gas flow characteristics can vary due to machining variability. The different gas conductance between RF gas breaks formed from separate components can result in different etch rates on different portions of a substrate as well as difference in etch performance between processing regions, for example, in a tandem processing chamber. By contrast, RF gas breaks manufactured using AM techniques can reduce variability between components allowing for more consistency in gas conductance between different RF gas break components.

Additionally, non-AM techniques are more limited in the ability to form complex gas flow paths and interior geometries. Moreover, complex geometries can include internal structures that reduce the amount of material needed to form the RF gas break.

Although the remaining disclosure will identify specific etching processes using the disclosed technology, it will be readily understood that the systems and methods are equally applicable to a variety of other processes as can occur in the described chambers. Accordingly, the technology should not be considered to be so limited as for use with the described etching processes alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example plasma processing chamber.

FIG. 2 shows a schematic cross-sectional partial view of an example plasma processing chamber.

FIG. 3 shows a schematic cross-sectional partial view of an example tandem plasma processing system.

FIG. 4 shows a schematic cross-sectional view of an example RF gas break coupled to a gas line and an electrode.

FIG. 5A shows a schematic cross-sectional view of an example RF gas break.

FIG. 5B shows an end view of the RF gas break of FIG. 5A.

FIG. 6 shows a schematic cross-sectional view of an example RF gas break.

FIG. 7 shows a schematic cross-sectional view of an example RF gas break.

FIG. 8 shows a schematic cross-sectional view of an example RF gas break.

FIG. 9 shows a schematic cross-sectional view of an example RF gas break.

FIG. 10 shows a schematic cross-sectional view of an example RF gas break.

FIG. 11 shows a schematic cross-sectional view of an example RF gas break.

FIG. 12 shows an end view of an example RF gas break.

FIGS. 13-14 show end views of example RF gas breaks showing different gas path cross sectional geometries.

FIG. 15 shows a schematic cross-sectional view of an example RF gas break.

FIGS. 16A-B show an example interior structure of an RF gas break.

FIGS. 17A-B show an example interior structure of an RF gas break.

FIG. 18 shows an example interior structure of an RF gas break.

FIG. 19 shows an example interior structure of an RF gas break.

FIGS. 20A-D show example infill pattern cross sections of an example interior structure of an RF gas break.

FIG. 21 shows a schematic cross-sectional view of an example RF gas break.

FIG. 22 is a flow diagram of an example process for manufacturing an RF gas break for a plasma processing system.

FIG. 23 is a block diagram of an example generic computing system.

Like reference numbers and designations in the various drawings indicate like elements.

### DETAILED DESCRIPTION

The present specification describes technologies for providing an impedance matched electrical break for use in a plasma-based processing chamber. The electrical break can be a RF gas break formed using an insulated segment of a gas line that isolates an electromagnetically charged gas distribution nozzle from a grounded gas line. Electrical isolation can prevent plasma ignition within the gas line. The RF break also provides one or more gas flow paths that can provide particular mixing of component process gases prior to entering the gas distribution nozzle. Gas flow paths can be configured to have a geometry that provides a particular gas flow length greater than a straight path, which can improve control over gas conductance into a plasma processing chamber. Embodiments of the present specification include RF gas break design enabled by additive manufacturing to provide greater control in impedance matching and design of gas flow paths.

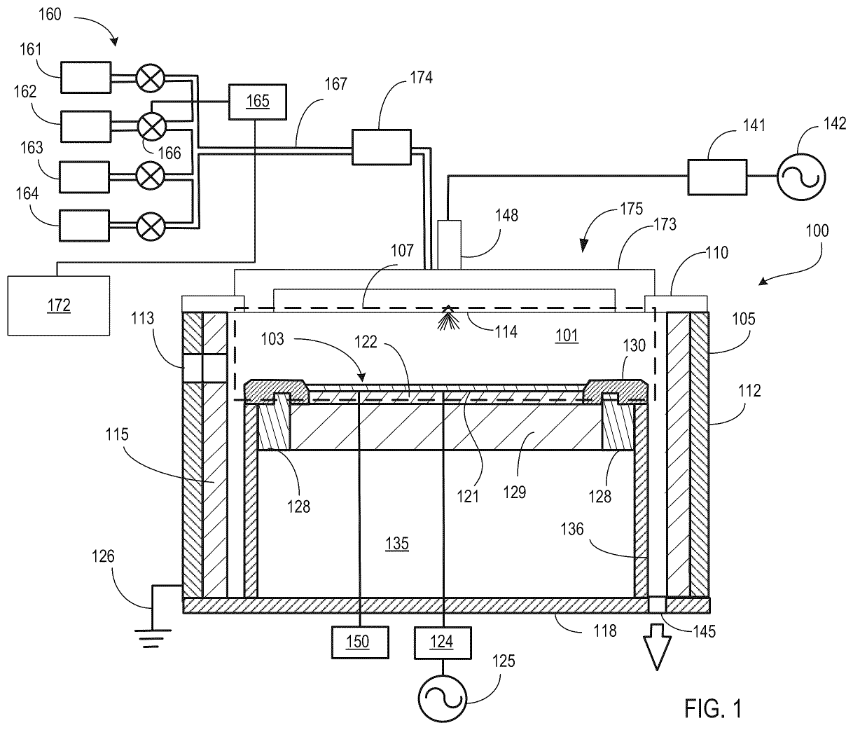

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by a radio frequency (“RF”) power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100.

Electrode 121 can be coupled with a DC power source 150. The power source 150 can provide a chucking voltage of about 200 volts to about 2000 volts to the electrode 121. The power source 150 can also include a system controller for controlling the operation of the electrode 121 by directing a DC current to the electrode 121 for chucking and de-chucking the substrate 103. The ESC 122 can include heaters disposed within the and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers.

A gas delivery assembly 175 is coupled to the lid 110. The gas delivery assembly 175 includes a gas delivery nozzle 114 and a chillplate 173. The chillplate 173 provides thermal transfer from the gas delivery nozzle 114, which is exposed to the heat of the processing chamber. The chillplate 173 includes pathways for passing process gases, e.g., from gas line 167, to the gas delivery nozzle 114. The gas delivery nozzle 114 can include one or more openings for introducing the process gases from the sources 161, 162, 163, 164 of the gas panel 160 into the chamber volume 101.

After the process gases are introduced into the plasma processing chamber 100, the gases can be energized to form a plasma. Different sources can be used to couple energy, such as RF energy, to the process gases to form and maintain a plasma in the chamber volume 101 of the plasma processing chamber 100. Example sources include a capacitively coupled plasma (“CCP”) source and an inductively coupled plasma (“ICP”) source. A CCP source includes an electrode 148 adjacent to the plasma processing chamber 100. The electrode can further be coupled to the gas distribution nozzle 114, e.g., through the chillplate 113. When charged, the gas distribution nozzle 114 forms a first parallel plate of a capacitor having a second electrode, e.g., electrode 121 in the ESC 122. A power supply 142 can power the electrode 148 and gas distribution nozzle 114 through a match circuit 141 to capacitively couple energy to the process gas. The operation of the power supply 142 can be controlled by a controller, such as controller 165, that also controls the operation of other components in the plasma processing chamber 100.

A gas break 174 provides an electrical separation between gas line 167 and gas distribution nozzle 114. The gas break 174 is an insulating component that provides a specified impedance while providing one or more paths for process gases. The gas break 174 can be positioned between two gas line segments to separate a grounded portion from a charged portion, positioned between a gas line and an input to the gas distribution nozzle, or positioned between the gas line and the electrode 148, through which a gas path can lead to the gas distribution nozzle. The gas break 174 is described in greater detail below.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

Although described with respect to FIG. 1 as a process chamber including a substrate support disposed within a processing region of the chamber volume, two or more substrate supports can be disposed within the same chamber volume in respective processing regions, e.g., in respective processing stations. For example, a processing chamber 100 can be a tandem processing chamber including two processing regions each with respective substrate supports configured to retain respective wafers during etching process(es). The processing chamber 100 can include two or more processing regions within the chamber volume 101 to facilitate parallel processing of two or more substrates in respective processing regions. The processing regions can be substantially isolated such that an etching process in a first processing region has minimal effect on an etching process in a second processing region and vice-versa.

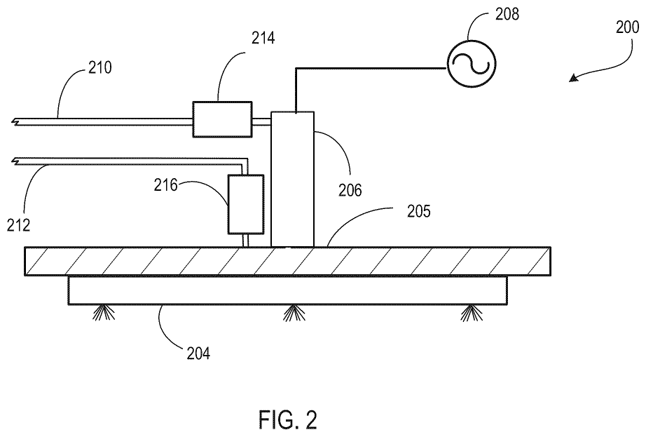

FIG. 2 shows a schematic cross-sectional partial view 200 of an example plasma processing chamber. The portion of the plasma processing chamber shown in FIG. 2 includes a gas delivery nozzle 204, chillplate 205, and RF electrode block 206. The gas delivery nozzle 204, chillplate 205, and RF electrode block 206 can be similar to gas delivery nozzle 114, chillplate 173, and electrode 148 of FIG. 1.

The RF electrode block 206 is coupled to the gas delivery nozzle 204 through the chillplate 205. When RF power is applied by power supply 208 the RF electrode block 206 and gas delivery nozzle 204 becomes electrically charged. A gas panel (not shown) supplies various process gases to the gas delivery nozzle. The process gases can be delivered to different portions of the gas delivery nozzle 204 so that the process gases can be distributed to different areas of the processing region. In the example shown in FIG. 2, two gas lines 210, 212 provide process gases from the gas panel and to the gas delivery nozzle 204. Gas line 210 provides process gases to a center region of the gas delivery nozzle 204. Gas line 212 provides process gases to an edge region of the gas delivery nozzle 204.

For example, in some implementations, the gas delivery nozzle 204 can include two separate plenums formed within the body of the gas delivery nozzle 204. A first plenum can be coupled to the gas line 210 and to one or more output paths for providing a mixture of process gases into a central region of the plasma processing chamber. A second plenum can be coupled to the gas line 212 and to one or more output paths for providing a mixture of process gases into an edge region of the plasma processing chamber. The amount and pressure of process gases supplied to each plenum can be independently controlled by controlling the gas delivery in each gas line 210, 212. In other implementations, there can be additional plenums formed in the gas delivery nozzle 204. Each of these additional plenums can be supplied by a separate gas line that allows for independent control of etch gases and gas pressures supplied to each plenum. This can provide greater control over the distribution of etch gases within the processing chamber, for example, to provide better control over etch performance to an entire substrate.

Gas line 210 can be coupled to the gas delivery nozzle 204 through a housing or structure of the RF electrode block 206. Alternatively, gas line 210 can be coupled to the gas delivery nozzle 204 without passing through the RF electrode block 206. Gas line 212 can be coupled to the gas delivery nozzle 204 at an edge position of the gas delivery nozzle 204.

Gas lines 210 and 212 are electrically grounded and typically are made from a conductive material, e.g., metal. However, the RF electrode block 206 and gas delivery nozzle 204 are electrically charged when powered by the power supply 208. To isolate the grounded gas lines 210 and 212 from the electrically charged RF electrode block 206 and gas delivery nozzle 204, respective RF gas breaks 214 and 216 are positioned between the respective gas lines and the electrically charged components. Thus, in the example shown in FIG. 2, there are two RF gas breaks, one for each gas line. In other implementations a single gas line may supply the process gases for the gas delivery nozzle. In that case, only one RF gas break may be needed. In some other implementations, additional gas lines can be used to supply process gases to the gas delivery nozzle. For example, when gases can be distributed to additional regions of the processing chamber. In such cases, an RF gas break can be provided for each independent gas line.

Each RF gas break 214, 216 are configured to provide a particular impedance over the particular RF frequencies applied to the RF electrode block 206 to prevent plasma ignition within the gas lines 214, 216. The RF gas breaks are formed from a suitable insulating material. In some implementations, the RF gas breaks are formed out of a thermoplastic material such as polyether ether ketone (“PEEK”). Additionally, as will be described in greater detail below, each RF gas break 214, 216 includes one or more gas flow paths that facilitate mixing of component process gases into a particular etch gas mixture provided to the gas delivery nozzle. The one or more gas flow paths also have a particular path geometry that provides a particular gas conductance to the gas delivery nozzle.

While in some implementations, the RF gas break can be formed of PEEK, in other implementations, the RF gas break can be formed from different materials. For example, the RF gas break can be formed from other thermoplastic materials including polyamidimide e.g., Torlon® or other suitable plastics. In another example, the RF gas break can be formed from a ceramic material including Al₂O₃, AlN, silicon carbide, silicon nitride, ceramic matrix composites or other suitable ceramic materials.

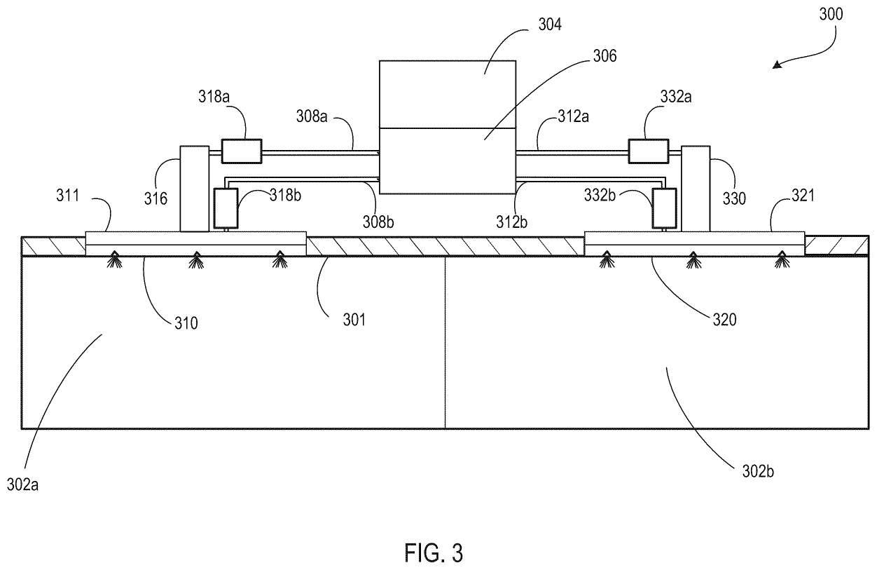

FIG. 3 shows a schematic cross-sectional partial view of an example tandem plasma processing chamber 300. The tandem plasma processing chamber 300 includes two processing regions 302a, 302b, e.g., two processing stations, within a chamber volume where each processing region is configured with components described above with respect to processing region 107 in FIG. 1. A single lid portion 301 can be used to enclose both processing regions 302a and 302b.

In a tandem chamber, a single gas panel 304 can be used with a gas switching structure 306 to supply different process gases to each processing region 302a, 302b. Thus, a first pair of gas lines 308a, 308b provide process gases to gas delivery nozzle 310 for processing region 302a. Gas delivery nozzle 310 is coupled to chillplate 311. A second pair of gas lines 312a, 312b provide process gases to gas delivery nozzle 320 for processing region 302b. Gas delivery nozzle 320 is coupled to chillplate 321.

Gas line 308a delivers gas to a central portion of gas delivery nozzle 310 through RF electrode block 316. Gas line 308b delivers gas to an edge portion of the gas delivery nozzle 310. Respective RF gas breaks 318a and 318b electrically separate the first pair of gas lines 308a, 308b from the gas delivery nozzle 310 and RF electrode block 316.

Gas line 312a delivers gas to a central portion of gas delivery nozzle 320 through RF electrode block 330. Gas line 312b delivers gas to an edge portion of the gas delivery nozzle 320. Respective RF gas breaks 332a and 332b electrically separate the second pair of gas lines 312a, 312b from the gas delivery nozzle 320 and RF electrode block 330.

As described below in greater detail, the RF gas breaks can be formed using additive manufacturing. Using additive manufacturing can reduce variability between different RF gas breaks. When placed in a plasma-processing system, this reduced variability can help ensure that etch rates are consistent between, for example, edge region etching and central region etching of a substrate. Moreover, when placed in a tandem plasma processing chamber such as that shown in FIG. 3, the reduced variability can aid in matching etch rates between processing regions applying a same etching operation.

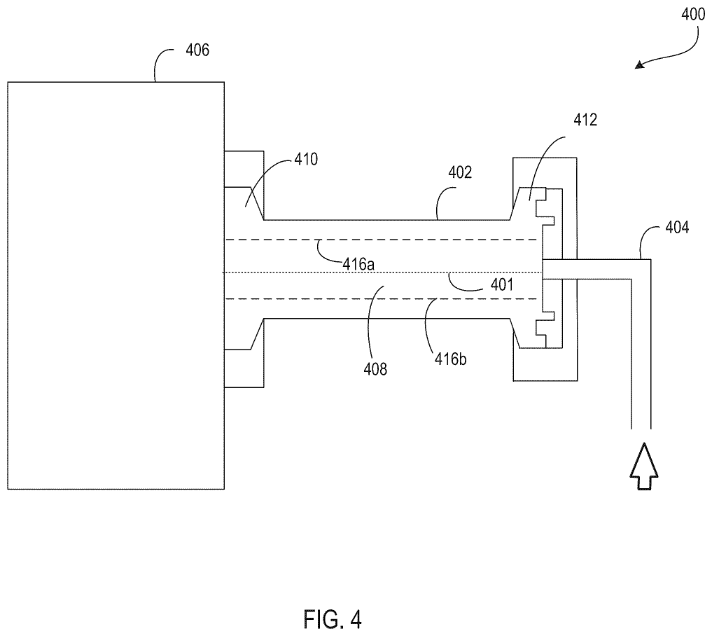

FIG. 4 shows a schematic cross-sectional view 400 of an example RF gas break 402 coupled to a gas line 404 and an RF electrode block 406. The RF gas break 402, gas line 404, and RF electrode block 406 can be similar to RF gas break 214, gas line 210 and RF electrode block 206 shown in FIG. 2. The RF gas break 402 includes a cylindrical portion 408 with a first flange 410 at a first end and a second flange 412 at a second end. In particular, the cylindrical portion 408 extends from the first flange 410 to the second flange 412 such that the second flange 412 is disposed a specified distance from the first flange 410. The first flange 410 and the second flange 412 have end surfaces perpendicular to a central axis 401 running longitudinally through the cylindrical portion 408. The first flange 408 is configured to couple the RF gas break 402 to the RF electrode block 406, for example, by clamping the first flange 408 to the RF electrode block 406. The second flange 412 is configured to couple the RF gas break 402 to the gas line 404, for example, by clamping the second flange 412 to the gas line 404. Alternatively, the flanges facilitate coupling the RF gas break 402 to the gas line and the gas delivery nozzle, for example, when supplying process gases to an edge region of the gas delivery nozzle.

While the RF gas break 402 is described as having a cylindrical portion 408 that has a circular cross section, the RF gas break can be designed with different cross-sectional geometries including, for example, oval, triangular, square, rectangular, or other n-gon (n>2) such as hexagonal.

The RF gas break 402 is formed from a single piece of material, e.g., a plastic material such as PEEK or a ceramic material, and includes a pair of gas flow paths 416a, 416b formed within the body of the RF gas break 402 and parallel to the central axis 401. The pair of gas flow paths 416a, 416b provide a pathway for process gases to flow from gas line 404 into the RF electrode block 406. While illustrated as straight lines, the gas flow paths can take various different geometries, as described in greater detail below. Although the path geometry can have various curvatures or angles, each path generally progresses along the central axis to carry process gases through the RF gas break 402. Additionally, different numbers of gas flow paths can be formed in the body of the RF gas break 402, which will be described in greater detail below.

The RF electrode block 406 can include a gas flow path that aligns with an end surface of the RF gas break 404 at the first flange 410 to allow the process gases to continue to a gas delivery nozzle. In particular, the interface between the RF gas break 402 and the gas line 404 and RF electrode block 406, respectively, are configured to allow the gas to flow from one component to the next. For example, the interface between the gas line 404 and the RF gas break 402, at second flange 412, can include a gap or channel that allows gas to flow from the single path of the gas line 404 into the two gas flow paths 416a, 416b of the RF gas break 402.

The dimensions of the RF gas break 402 can depend on the material, the RF frequencies used with the RF electrode block 406, and a desired impedance. In some implementations, the RF gas break 402 is formed from PEEK and has a length between 3 and 3.5 inches and a diameter of about 1 inch. However, the dimensions can change based on the characteristics of the RF electrode block 406.

In some implementations, the RF gas break is formed using additive manufacturing techniques that result in a single piece of material once the additive manufacturing process is completed, e.g., a plastic material such as PEEK, or a ceramic material. Additive manufacturing of the RF gas break is described in greater detail below.

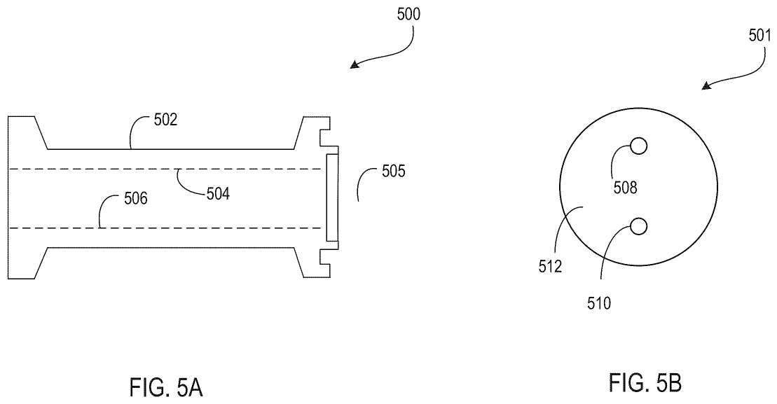

FIG. 5A shows a schematic cross-sectional view 500 of an example RF gas break 502. FIG. 5B shows an end view 501 of the RF gas break of 502 FIG. 5A.

The RF gas break 502 is similar to RF gas break 402 of FIG. 4 and includes flanges at each end to facilitate coupling the RF gas break 502 to the RF electrode block and gas line, respectively. Alternatively, the flanges facilitate coupling the RF gas break 502 to the gas line and the gas delivery nozzle, for example, when supplying process gases to an edge region of the gas delivery nozzle. In other implementations, the flanges may be omitted and the RF gas break can be attached to other components using other suitable techniques. Various types of flange designs can be used including, for example, vacuum fitting flanges such as CF, KF, ISO flanges, or custom flanges with O-ring seals in-between.

In some implementations, the materials involved can lead to particular ways of attaching the RF gas break. For example, in an implementation where the RF gas break is made from a ceramic material, the RF gas break can be directly bonded to the gas delivery assembly with a bonding material e.g., formed from an organic material or a metal bonding material. Similarly, each gas line end can also be bonded to ceramic. Alternative ways of coupling or attaching the RF gas break include having a threaded connection, for example, incorporating an O-ring seal to prevent vacuum leaks, e.g., an SAE threaded fitting.

The example RF gas break 502 includes two gas flow paths 504 and 506. In this example, the gas flow paths are straight paths from one end of the RF gas break 502 to the other end. Process gases from the gas line enter one of two input apertures 508 and 510 to gas flow paths 504 and 506, respectively.

As shown in end view 501, the input apertures 508 and 510 are positioned on opposite sides of the end face 512 of the RF gas break 502. The output apertures can be similarly positioned on the other end face of the RF gas break (not shown). In other implementations, the input apertures can be positioned at different angles from one another. For example, taking the position of the first input aperture as zero, instead of the second input aperture being at 180 degree position as shown in FIG. 5B, the second input aperture can be at 90 degrees or some other position relative to the first input aperture. Additionally, the two gas flow paths need not be equidistant from a longitudinal centerline of the RF gas break. For example, one gas flow path can be an “outer” gas flow path further from the center point while another gas flow path can be an “inner” gas flow path closer to the center point.

The length of the RF gas break 502 is configured to provide a particular impedance value to isolate the grounded gas line from an RF electrode block. The RF gas break 502 can be formed from a plastic material such as PEEK or a ceramic material.

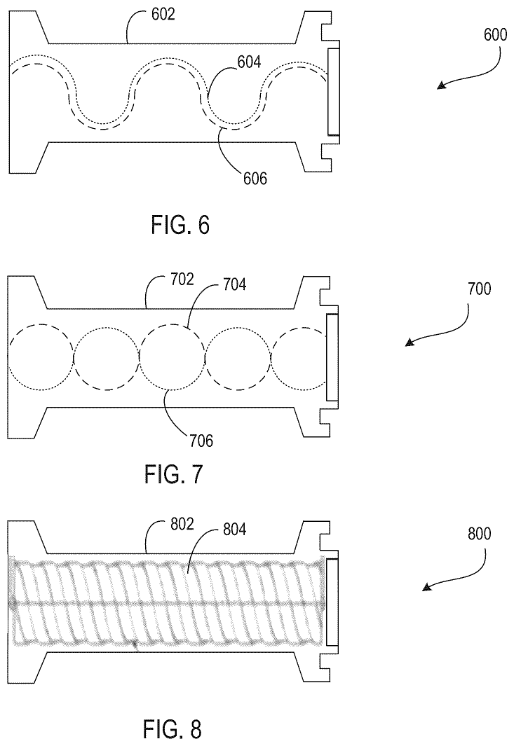

FIG. 6 shows a schematic cross-sectional view 600 of an example RF gas break 602. The RF gas break 602 has a similar outside shape and form factor to RF gas break 502 of FIG. 5 and includes flanges at each end to facilitate coupling the RF gas break 602 to other components, e.g., gas line, RF electrode block, or gas delivery assembly. In other implementations, the flanges may be omitted and the RF gas break can be attached to other components using other suitable techniques as described above.

The example RF gas break 602 includes two gas flow paths 604 and 606. In this example, the gas flow paths are serpentine paths from one end of the RF gas break 602 to the other end. In particular, gas flow paths 604 and 606 form a double serpentine path in which each individual path tracks a same distance from the other path as they form a similar serpentine shape along the length of the RF gas break 602. Process gases from the gas line enter one of two input apertures (not shown) to gas flow paths 504 and 506, respectively. The location of the input apertures, and similarly output apertures, can vary on the end faces of the RF gas break 602 based on the points of the double serpentine paths that intersect with an end face.

The serpentine path increases the length of the gas flow path through the RF gas break as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

FIG. 7 shows a schematic cross-sectional view 700 of an example RF gas break 702. The RF gas break 702 has a similar outside shape and/or form factor to RF gas break 502 of FIG. 5 and includes flanges at each end to facilitate coupling the RF gas break 702 to other components, e.g., gas line, RF electrode block, or gas delivery assembly. In other implementations, the flanges may be omitted and the RF gas break can be attached to other components using other suitable techniques as described above.

The example RF gas break 702 includes two gas flow paths 704 and 706. In this example, the gas flow paths are double helical paths from one end of the RF gas break 702 to the other end. In particular, each gas flow path 704, 706 takes a helical path through the length of the RF gas break 702. The respective helical paths are intertwined in a double helix pattern. Process gases from the gas line enter one of two input apertures (not shown) to gas flow paths 704 and 706, respectively. The location of the input apertures, and similarly output apertures, can vary on the end faces of the RF gas break 702 based on the points of the double helix path that intersects with an end face.

The double helix path increases the length of the gas flow path through the RF gas break as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

FIG. 8 shows a schematic cross-sectional view 800 of an example RF gas break 802. The RF gas break 802 has a similar outside shape and/or form factor to RF gas break 502 of FIG. 5 and includes flanges at each end to facilitate coupling the RF gas break 802 to other components, e.g., gas line, RF electrode block, or gas delivery assembly. In other implementations, the flanges may be omitted and the RF gas break can be attached to other components using other suitable techniques as described above.

The example RF gas break 802 includes gas flow path 804. In this example, gas flow path 804 is a spiral path that coils around the interior of the RF gas break 802 from one end face to the other end face. For example, the gas flow path 804 can be a spiral channel that begins at a first end face and has a circular cross section on the plane of the end face. In some implementations, a second gas flow path can be incorporated having a similar shape and intertwined with the gas flow path 804. Process gases from the gas line enter an input aperture (not shown) to gas flow paths 804. The location of the input aperture, and similarly output aperture, can vary on the end faces of the RF gas break 802 based on the points of the spiral gas path that intersect with an end face.

The spiral gas path increases the length of the gas flow path through the RF gas break 802 as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

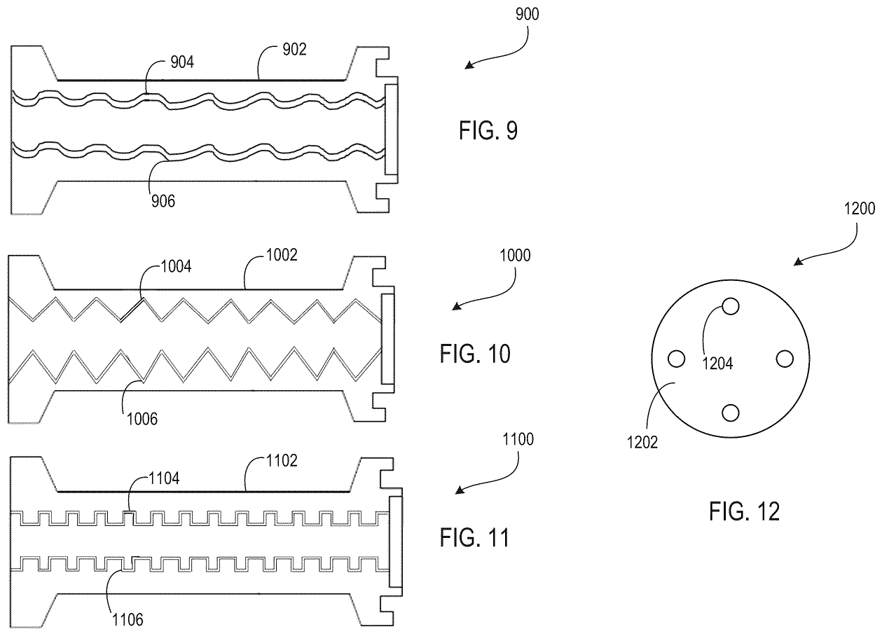

FIG. 9 shows a schematic cross-sectional view 900 of an example RF gas break 902. The RF gas break 902 has a similar outside shape and/or form factor to RF gas break 502 of FIG. 5 and includes flanges at each end to facilitate coupling the RF gas break 902 to other components, e.g., gas line, RF electrode block, or gas delivery assembly. In other implementations, the flanges may be omitted and the RF gas break can be attached to other components using other suitable techniques as described above.

The example RF gas break 902 two gas flow paths 904 and 906. In this example, the gas flow paths 904, 906 are serpentine paths that each pass through different portions of the RF gas break 902. For example, gas flow path 904 can be on an “upper” half of the RF gas break 902 while gas flow path 906 can be positioned on a “lower” half. Similarly, in the case of four gas flow paths, the other two gas paths can be positioned in the remaining quadrants of the RF gas break body. In other words, when viewed from an end face divided into four quadrants, a separate gas flow path can proceed in each respective quadrant.

Process gases from the gas line enter one of two input apertures (not shown) to gas flow paths 904 and 906, respectively. The location of the input apertures, and similarly output apertures, can vary on the end faces of the RF gas break 902 based on the points of the serpentine paths that intersect with an end face.

The serpentine path increases the length of the gas flow path through the RF gas break as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

FIG. 10 shows a schematic cross-sectional view of an example RF gas break 1002. The RF gas break 1002 has a similar outside shape and/or form factor to RF gas break 502 of FIG. 5 and includes flanges at each end to facilitate coupling the RF gas break 1002 to other components, e.g., gas line, RF electrode block, or gas delivery assembly. In other implementations, the flanges may be omitted and the RF gas break can be attached to other components using other suitable techniques as described above.

The example RF gas break 1002 two gas flow paths 1004 and 1006. In this example, the gas flow paths 1004, 1006 are saw tooth paths that each pass through different portions of the RF gas break 1002. For example, gas flow path 1004 can be on an “upper” half of the RF gas break 1002 while gas flow path 1006 can be positioned on a “lower” half. Similarly, in the case of four gas flow paths, the other two gas paths can be positioned in the remaining quadrants of the RF gas break body. In other words, when viewed from an end face divided into four quadrants, a separate gas flow path can proceed in each respective quadrant.

Process gases from the gas line enter one of two input apertures (not shown) to gas flow paths 1004 and 1006, respectively. The location of the input apertures, and similarly output apertures, can vary on the end faces of the RF gas break 1002 based on the points of the saw tooth paths that intersect with an end face.

The saw tooth paths increase a length of the gas flow path through the RF gas break as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

FIG. 11 shows a schematic cross-sectional view 1100 of an example RF gas break 1100. The RF gas break 1102 has a similar outside shape and/or form factor to RF gas break 502 of FIG. 5 and includes flanges at each end to facilitate coupling the RF gas break 1102 to other components, e.g., gas line, RF electrode block, or gas delivery assembly. In other implementations, the flanges may be omitted and the RF gas break can be attached to other components using other suitable techniques as described above.

The example RF gas break 1102 two gas flow paths 1104 and 1106. In this example, the gas flow paths are square wave shaped paths that each pass through different portions of the RF gas break 1102. For example, gas flow path 1104 can be on an “upper” half of the RF gas break 1102 while gas flow path 1106 can be positioned on a “lower” half. Similarly, in the case of four gas flow paths, the other two gas paths can be positioned in the remaining quadrants of the RF gas break body. In other words, when viewed from an end face divided into four quadrants, a separate gas flow path can proceed in each respective quadrant.

Process gases from the gas line enter one of two input apertures (not shown) to gas flow paths 1104 and 1106, respectively. The location of the input apertures, and similarly output apertures, can vary on the end faces of the RF gas break 1102 based on the points of the saw tooth paths that intersect with an end face.

The square wave shaped paths increase the length of the gas flow path through the RF gas break as compared to the linear path shown in FIG. 5 without changing the overall dimensions of the RF gas break. Increased path length, which increases a distance that gas flows to reach the gas distribution nozzle, can help control a gas conductance so that a consistent etch rate is produced in a plasma processing chamber.

While particular gas flow path geometries are illustrated in FIGS. 5-11, other path geometries are possible. Different path geometries may provide different flow and gas mixing characteristics. In addition to varied path geometries, the position of the paths within the body of the RF gas break can vary as well. For example, the position of one path relative to another can vary. For example, while generally illustrated as having a starting point at an input aperture positioned at 180 degrees rotation around a center of the end face of the RF gas break, other rotational angles are possible. Additionally, the distance of a given path from a longitudinal centerline of the RF gas break extending through the length of the RF gas break can also vary. For example, one gas flow path can be closer to the center line than another gas flow path.

Additionally, while two flow paths are shown, other numbers are possible, e.g., four gas flow paths each having a starting point rotated 90 degrees about the end face of the RF gas break. FIG. 12 shows an example end view 1200 of an RF gas break 1202. The gas break 1202 includes four apertures 1204, each coupled to a corresponding gas flow path. While shown at substantially equal radial distance, the individual gas paths can have apertures at different radial distances. The aperture location can be driven by the geometry of the gas flow path, e.g., the point on the gas flow path in which it intersects with the end face of the RF gas break. Alternatively, the aperture location can be indicative of paths themselves having different positions within the body of the RF gas break. Other numbers of gas flow paths can be implemented as suitable for a given gas flow and impedance requirements of the RF gas break.

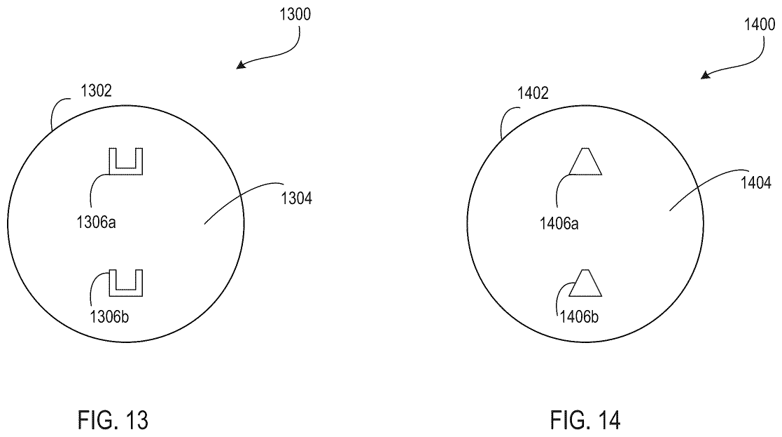

In some implementations, the respective gas flow paths, e.g., the gas flow paths shown in FIGS. 5-11, can have a circular or square cross section along the path. However, other path cross-sections are possible including, for example, triangular, rectangular, polygonal e.g., hexagonal, oval, etc. Different path-cross sections may provide different flow and gas mixing characteristics. FIGS. 13-14 show examples of path cross sections.

FIG. 13 shows an end view 1300 of an example RF gas break 1302. The RF gas break 1302 has an end face 1304. The end face can further include a flange structure, which is omitted here for clarity. The end face 1304 includes two input apertures 1306a, 1306b for respective gas flow paths. Each gas flow path has a “U” shaped cross section as illustrated by the input apertures 1306a, 1306b, rather than a circular or square shaped cross section.

FIG. 14 shows an end view 1400 of an example RF gas break 1402. The RF gas break 1402 has an end face 1404. The end face can further include a flange structure, which is omitted here for clarity. The end face 1404 includes two input apertures 1406a, 1406b for respective gas flow paths. Each gas flow path has a “dovetail” or trapezoidal cross section as illustrated by the input apertures 1406a, 1406b, rather than a circular or square shaped cross section.

In addition to varied gas flow path geometries, an internal structure of the RF gas break can incorporate various designs. Thus, instead of a solid body other than the gas flow paths, the interior structure can have designs that reduce materials used while maintaining a required strength of the RF gas break.

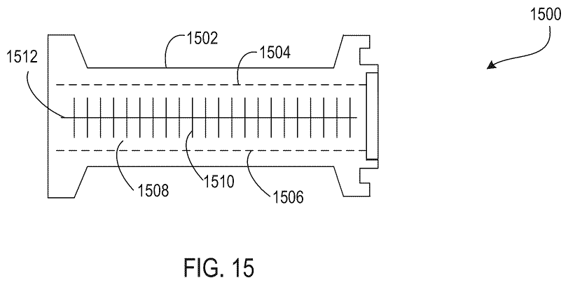

FIG. 15 shows a schematic cross-sectional view 1500 of an example RF gas break 1502. The RF gas break 1502 has a similar outside shape to RF gas break 502 of FIG. 5 and includes flanges at each end to facilitate coupling the RF gas break 1502 to the RF electrode block and gas line, respectively. In other implementations, the flanges may be omitted and the RF gas break can be attached to other components using other suitable techniques.

The example RF gas break 1502 includes two gas flow paths 1504 and 1506. In this example, the gas flow paths are straight paths from one end of the RF gas break 1502 to the other end although other path geometries can be used. Process gases from the gas line enter one of two input apertures to gas flow paths 1504 and 1506, respectively. Process gases exit the RF gas break 1502 at the other end face of the RF gas break 1502, for example, to enter a gas flow path through an RF electrode block or gas flow path to a gas delivery nozzle.

The RF gas break 1502 further includes an interior structure 1508. The interior structure 1508 formed within a central region of the RF gas break 1502 replaces a solid structure that is unbroken outside of the respective gas flow paths. The interior structure 1508 can be designed to reduce materials used while being configured to provide a specified component strength. In particular, when formed using additive manufacturing, the interior structure can correspond to a particular infill pattern that is configured to provide a particular density (e.g., a ratio of solid to empty space), strength, and rigidity.

Different types of interior structures can be used. FIG. 15 illustrates an example rib structure in which the interior length of the RF gas break includes a number of ribs 1510 joined by a cross structure 1512 that leaves a number of empty spaces within the body of the RF gas break. The empty/hollow spaces in this embodiment, as well as with other interior structures, can terminate prior to an end face of the RF gas break to ensure that there are no “line of sight” paths to potentially cause an RF voltage breakdown across the RF gas break.

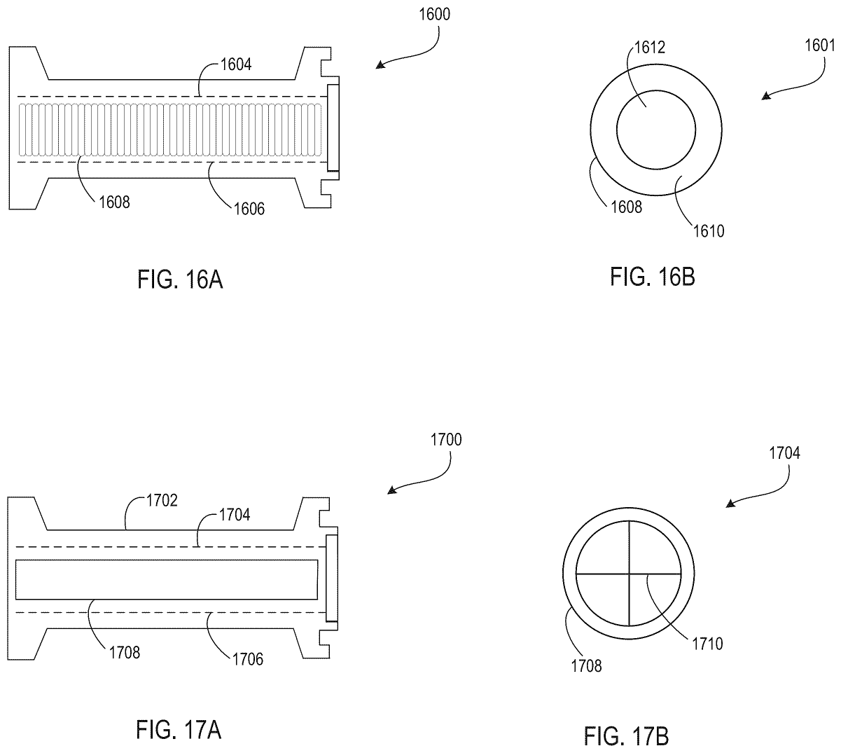

FIG. 16A illustrates an example interior coil structure 1608 in which the interior lengths of a central portion of the RF gas 1600 break includes a coil shaped structure. FIG. 16B shows a schematic cross-sectional view 1601 of an example coil structure 1608.

The RF gas break 1600 has a similar outside shape to RF gas break 502 of FIG. 5 and includes flanges at each end to facilitate coupling the RF gas break 1600 to the RF electrode block and gas line, respectively. In other implementations, the flanges may be omitted and the RF gas break can be attached to other components using other suitable techniques.

The example RF gas break 1600 includes two gas flow paths 1604 and 1606. In this example, the gas flow paths are straight paths from one end of the RF gas break 1600 to the other end although other path geometries can be used. Process gases from the gas line enter one of two input apertures to gas flow paths 1604 and 1606, respectively. Process gases exit the RF gas break 1600 at the other end face of the RF gas break 1600, for example, to enter a gas flow path through an RF electrode block or gas flow path to a gas delivery nozzle.

The RF gas break 1600 further includes an interior coil structure 1608. The interior coil structure can be a helical coil that extends along a length of the RF gas break 1600. In some implementations, the coil interior 1610 is solid, while in others the coil structure 1608 has a hollow interior within the coil. Additionally, the coil structure 1608 surrounds an interior cavity 1612 along a longitudinal axis of the coil that is hollow as shown in cross-sectional view 1601 of FIG. 16B. Alternative to a spiral shape, the interior coil structure can be formed from an array of adjacent torus shapes forming a stacked set of rings and having a hollow interior.

FIG. 17A illustrates an example cross shaped internal structure 1702 in which the interior length of a central portion of the RF gas break 1700 includes a hollow cylinder structure 1708 with an interior cross shape.

The RF gas break 1700 has a similar outside shape to RF gas break 502 of FIG. 5 and includes flanges at each end to facilitate coupling the RF gas break 1700 to the RF electrode block and gas line, respectively. In other implementations, the flanges may be omitted and the RF gas break can be attached to other components using other suitable techniques.

The example RF gas break 1700 includes two gas flow paths 1704 and 1706. In this example, the gas flow paths are straight paths from one end of the RF gas break 1700 to the other end although other path geometries can be used. Process gases from the gas line enter one of two input apertures (not illustrated) to gas flow paths 1704 and 1706, respectively. Process gases exit the RF gas break 1700 at the other end face of the RF gas break 1700, for example, to enter a gas flow path through an RF electrode block or gas flow path to a gas delivery nozzle.

In particular, as shown in FIG. 17A, a view of the interior structure along the length of the RF gas break 1700 shows a cylindrical structure 1708 within the body of the RF gas break. FIG. 17B shows a cross-sectional view 1704 illustrating cross beams 1710 within the hollow portion of the cylindrical structure 1708.

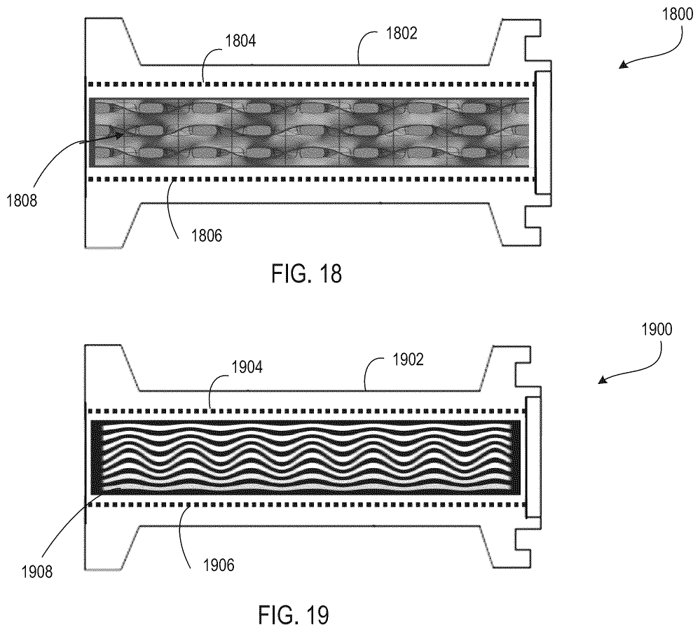

FIG. 18 shows an example interior structure of an RF gas break 1802. RF gas break 1802 includes gas paths 1804 and 1806 as dashed lines for reference. The RF gas break 1802 also includes interior structure 1808. The interior structure 1808 can form a gyroid pattern. The gyroid pattern can be formed, for example, as a particular infill pattern during additive manufacturing. A gyroid pattern may be selected because it can provide a high strength to density ratio, requiring less material to provide a specified strength of the RF gas break 1802.

FIG. 19 shows an example interior structure of an RF gas break 1902. RF gas break 1902 includes gas paths 1904 and 1906 as dashed lines for reference. The RF gas break 1902 also includes interior structure 1908. The interior structure 1908 can form a stacked wave shape. The stacked wave shape can be, for example, a number of thin wavy sheets attached to sidewalls of the RF gas break that are stacked with an empty space layer between each one.

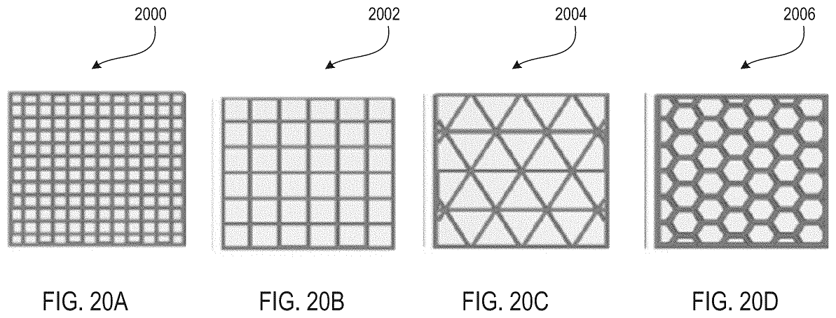

FIGS. 20A-D show example infill pattern cross sections of an example interior structure of an RF gas break. Each infill pattern can correspond to a particular lattice structure. FIG. 20A shows a rectilinear pattern 2000 of small square openings within a cross section. FIG. 20B shows a grid pattern 2002 of larger square openings within a cross section. The size of the grid can vary depending on the particular specified strength and rigidity of the resulting RF gas break. FIG. 20C shows a pattern of triangle shapes 2004 forming an internal structure. FIG. 20D shows a honeycomb pattern 2006, e.g., where each segment is hexagonal or circular in shape. Other infill patterns can be used and can be configured to provide a particular lattice structure. These infill patterns can be the same in multiple directions, e.g., a uniform pattern within the body of a cylindrical or cuboid internal structure or simply a cross section.

Each of these can be positioned within the body of a particularly formed RF gas break. For example, the RF gas break can include an outer surface, one or more formed gas paths, and one of the internal structures formed, for example, as a particular infill pattern provided through additive manufacturing. The internal structure can occupy a portion of the center of the RF gas break, e.g., to a specified radial distance, with the gas flow paths being positioned between the interior structure and the outer surface of the RF gas break.

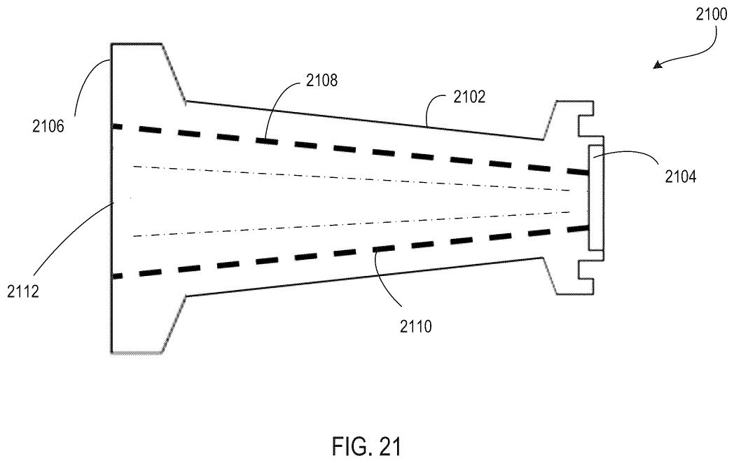

FIG. 21 shows a schematic cross-sectional view 2100 of an example RF gas break 2102. The RF gas break 2102, in contrast for example to RF gas break 502, has a conical body section instead of cylindrical. For example, the narrow end 2104 can correspond to an end that is coupled to a gas line. The wider end 2106 can correspond to an end that couples to an RF electrode block or a gas delivery assembly. Gas paths 2108, 2110 illustrate a general path, e.g., angled from the narrow and toward the wider end. However, the dashed lines simply represent one of many possible gas flow path geometries as described above. Similarly, internal structure 2112 is representative of possible internal structure dimensions, which in this example, follow the conical shape of the RF gas block 2102. The configuration or pattern fill for the internal structure 2112 can vary as described above.

In some embodiments, additive manufacturing e.g., three-dimensional printing (or 3-D printing), may be used to produce (or make) the RF gas breaks described in this specification. Using additive manufacturing allows for greater control over gas flow path geometries and formation of complex internal structures that can reduce the amount of material used. Additionally, the precision of additive manufacturing can help insure similar impedance and gas flow properties between individual RF gas break components. That allows for greater control over impedance matching between RF gas breaks for a single processing region or between processing regions of tandem chambers.

In one embodiment, a computer (CAD) model of the required part is first made and then a slicing algorithm maps the information for every layer. A layer starts off with a thin distribution of powder spread over the surface of a powder bed. A chosen binder material then selectively joins particles where the object is to be formed. Then a piston which supports the powder bed and the part-in-progress is lowered in order for the next powder layer to be formed. After each layer, the same process is repeated followed by a final heat treatment to make the object. Since 3-D printing can exercise local control over the material composition, microstructure, and surface texture, various (and previously inaccessible) geometries may be achieved with this method.

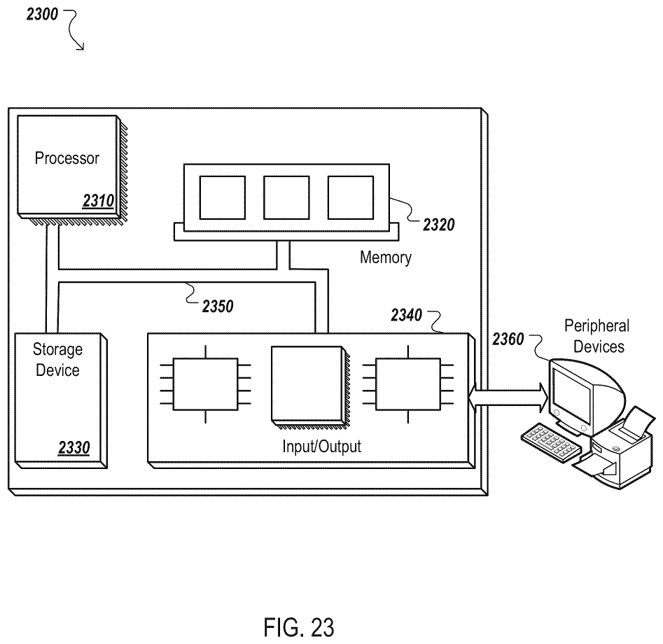

In one embodiment, an RF gas break as described herein may be represented in a data structure readable by a computer rendering device or a computer display device. FIG. 23 is a schematic representation of a computer system with a computer-readable medium according to one embodiment. The computer-readable medium may contain a data structure that represents the RF gas break. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the computer system to render the article represented by the data structure on a computer screen or a physical rendering device which may be an additive manufacturing device, such as a 3D printer.

In some embodiments, additive manufacturing techniques can be used in combination with other manufacturing techniques, e.g., subtractive manufacturing. For example, subtractive manufacturing can be used to modify/remove portions of the RF gas break and additive manufacturing can be used to add/modify portions of the RF gas break. The combination of techniques can be used during the initial process to manufacture the RF gas break or to modify/refurbish an existing RF gas break to repair damage or change a configuration of the RF gas break features.

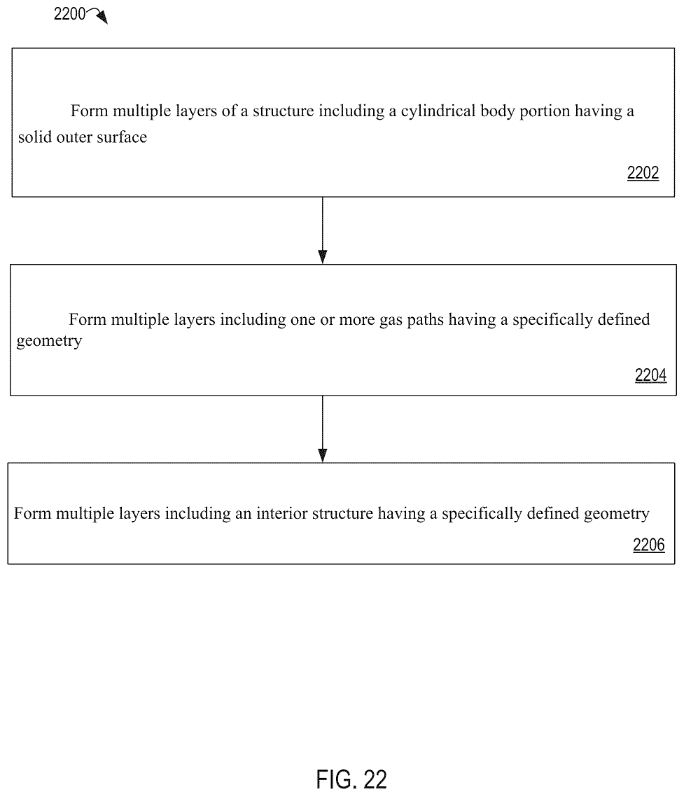

FIG. 22 is a flow diagram of an example process 2200 for manufacturing an RF gas break, for example, for use in a plasma based processing system. For convenience, the process 2200 will be described with respect to an additive manufacturing system that performs at least some steps of the process.

An additive manufacturing system forms multiple layers including a plastic cylindrical body portion having a solid outer surface (2202). The additive manufacturing system can receive, from a computer system, a data structure representative of the RF gas break, and use the data structure to form the multiple layers of the RF gas break.

The additive manufacturing system forms multiple layers including two or more gas flow paths within the cylindrical body and having a specifically defined geometry (2204). The gas flow paths can be positioned next to each other or in separate regions of the cylindrical body. The gas flow paths can be formed in the shape of various three dimensional geometries including serpentine, helical, or straight paths. Furthermore, a cross-section of each gas flow path can have a specified geometry including, for example, circular, square, “U” shaped, or trapezoidal.

The additive manufacturing system forms multiple layers including an interior structure within the cylindrical body having a specifically defined geometry (2206). Interior structures can be formed to reduce material usage while maintaining structural strength of the RF gas break. The interior structures can include forming multiple layers to generate a rib structure, a coil structure, or a cross beam structure within a center portion of the cylindrical body. In some other implementations, the data structure can include instructions for forming a particular infill pattern as the interior structure.

FIG. 23 is a block diagram of an example computer system 2300 that can be used to perform operations described above. The system 2300 includes a processor 2310, a memory 2320, a storage device 2330, and an input/output device 1440. Each of the components 2310, 2320, 2330, and 2340 can be interconnected, for example, using a system bus 2350. The processor 2310 is capable of processing instructions for execution within the system 2300. In one implementation, the processor 2310 is a single-threaded processor. In another implementation, the processor 2310 is a multi-threaded processor. The processor 2310 is capable of processing instructions stored in the memory 2320 or on the storage device 2330.

The memory 2320 stores information within the system 2300. In one implementation, the memory 2320 is a computer-readable medium. In one implementation, the memory 2320 is a volatile memory unit. In another implementation, the memory 2320 is a non-volatile memory unit.

The storage device 2330 is capable of providing mass storage for the system 2300. In one implementation, the storage device 2330 is a computer-readable medium. In various different implementations, the storage device 2330 can include, for example, a hard disk device, an optical disk device, a storage device that is shared over a network by multiple computing devices (e.g., a cloud storage device), or some other large capacity storage device.

The input/output device 2340 provides input/output operations for the system 2300. In one implementation, the input/output device 2340 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 2360, e.g., keyboard, printer and display devices. Other implementations, however, can also be used, such as mobile computing devices, mobile communication devices, set-top box television client devices, etc.

Although an example processing system has been described in FIG. 23, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller 165 and processes performed by controller 165 such as controlling of the gas panel and distribution of process gases to a plasma processing chamber, can be implemented in digital electronic circuitry, in tangibly-embodied computer software or firmware, in computer hardware, including the structures disclosed in this specification and their structural equivalents, or in combinations of one or more of them.

The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A system for semiconductor processing, the system comprising:
a chamber enclosing a first processing region;
a first substrate support within the chamber and configured to retain a first substrate in the first processing region of the chamber;
a plasma source configured to direct RF energy into the chamber;
a gas distribution manifold wherein the gas distribution manifold is operatively coupled to the chamber to introduce an etching gas comprising one or more gases from the gas distribution manifold to a gas delivery nozzle of the chamber; and
a gas break structure comprising an insulating material and having one or more gas flow paths formed within a body of the gas break structure, the gas break structure configured to provide a specified impedance when coupled between a grounded gas distribution manifold and an electrically charged gas delivery nozzle, the gas break structure further comprising an internal structure having a specified geometry comprising a repeating structure and one or more empty gaps between elements of the repeating structure.

2. The system of claim 1, wherein the one or more gas flow paths have a helical coil geometry.

3. The system of claim 1, wherein the one or more gas flow paths comprise two gas flow paths, the two gas flow paths have a double helical geometry.

4. The system of claim 1, wherein the one or more gas flow paths have a “U” shaped cross-section.

5. The system of claim 1, wherein the one or more gas flow paths have a dovetail shaped cross-section.

6. The system of claim 1, wherein the internal structure comprises a plurality of rib structures joined by one or more cross members.

7. The system of claim 1, wherein the internal structure comprises a coil structure surrounding a hollow interior.

8. The system of claim 1, wherein the internal structure comprises a hollow cylinder structure having a pair of cross beams within the hollow interior.

9. The system of claim 1, wherein the internal structure corresponds to a particular infill pattern, wherein the infill pattern comprises one or more of a grid pattern, a triangle pattern, a honeycomb pattern, a gyroid pattern, or a stacked wave pattern.

10. The system of claim 1, wherein the RF gas break is formed from one or more of a thermoplastic material or a ceramic material including ceramic matrix composites.

11. A gas break structure embodied in a machine-readable medium for designing, manufacturing, or testing a design, the gas break structure comprising:
a gas break body comprising an insulating material configured to provide a specified impedance, the gas break body having one or more gas flow paths formed within the body and having a particular path geometry, the gas break structure further comprising an internal infill structure having a specified geometry comprising a repeating structure and one or more empty gaps between elements of the repeating structure.

12. The gas break structure embodied in the machine readable medium of claim 11, wherein the one or more gas flow paths have a curved geometry comprising one or more of a helical coil, double helical coil, or spiral geometry.

13. The system of claim 1, wherein the one or more gas flow paths comprise a first gas flow path having a first radial distance from a center of the gas break body and a second gas flow path having a second radial distance from the center of the gas break body, wherein the second radial distance is greater than the first radial distance.

14. The system of claim 1, wherein the one or more gas flow paths have a n-gon cross section where n is greater than 2.

15. The system of claim 1, wherein the internal structure comprises a plurality of rib structures joined by one or more cross members.

16. The system of claim 1, wherein the internal structure comprises a coil structure surrounding an interior that is at least partially hollow.

17. The system of claim 1, wherein the internal structure corresponds to a particular infill pattern, wherein the infill pattern comprises one or more of a grid pattern, a triangle pattern, a honeycomb pattern, a gyroid pattern, or a stacked wave pattern.

18. A method of manufacturing a gas break structure, the method comprising:
forming, by an additive manufacturing system, a plurality of layers, the plurality of layers comprising:
a body having a solid outer surface;
two or more gas flow paths defined within the body, wherein the two or more gas flow paths extend along a longitudinal length of the body, each gas flow path having a specified path geometry; and
an internal infill structure occupying a portion of the body, the internal infill structure having a specified geometry comprising structural elements and one or more hallow spaces between the structure elements.

19. The method of claim 18, wherein forming the plurality of layers comprising the internal infill structure comprises forming a particular infill pattern for the internal infill structure, wherein the infill pattern comprises one or more of a grid pattern, a triangle pattern, a honeycomb pattern, a gyroid pattern, or a stacked wave pattern.

20. The method of claim 18, wherein forming the plurality of layers comprises the one or more gas flow paths comprises forming two or more curved paths extending longitudinally from a first end face of the body to a second end face of the body.
